(19) United States
(12) Patent Application Publication
(10) Pub. No.: US 2007/0262430 A1
(43) Pub. Date: Nov. 15, 2007

(54) Electric component, method of producing the same, substrate with built-in electric component, and method of producing the same

(75) Inventor: Soichiro Ibaraki, Miyazaki (JP)

Correspondence Address: TAKEUCHI & KUBOTERA, LLP, SUITE 202, 200 DAINGERFIELD ROAD, ALEXANDRIA, VA, 22314, US

(73) Assignee: Oki Electric Industry Co., Ltd.

(21) Appl. No.: 11/635,014

(22) Filed: Dec. 7, 2006

(30) Foreign Application Priority Data
May 9, 2006 (JP) 2006-130693

(51) Int. Cl. H01L 23/02; H01L 21/00

(52) U.S. Cl. 257/678; 438/106

(57) ABSTRACT

An electric component includes a substrate having a first surface and a second surface opposite to the first surface; a first conductive layer formed on the first surface; a second conductive layer formed on the second surface; an electrode formed on the first conductive layer; a resin portion formed on the first conductive layer such that a part of the electrode is exposed; and an external terminal electrically connected to the part of the electrode.

### BACKGROUND OF THE INVENTION AND RELATED ART STATEMENT

The present invention relates to an electric component having a conductive layer, and a substrate with a built-in electric component.

Recently, a dimension and a weight of a mobile device have been reduced drastically while a capability thereof has been improved. Accordingly, it is difficult to meet such a trend with a conventional component mounting technology. To this end, as one of System In Package (SIP) technologies, a substrate with a built-in component has been developed, in which a component is embedded in a Printed Wiring Board (PWB) instead of being mounted thereon.

Among methods of embedding a component in a substrate, there is a method of building-in an electric component called a Wafer Level Chip Size Package or a Wafer Level Chip Size Package (W-CSP). As an example of an electric component of the W-CSP type, Patent Reference 1 has disclosed a semiconductor component having a pad on one side thereof as an electrode.

Further, Patent Reference 2 has disclosed a substrate with a built-in electric component. In the substrate with the built-in electric component, two interlayer resin insulation layers having a conductive circuit and a via-hole are laminated on a resin substrate with a built-in electric component (IC chip). An aluminum pad disposed on the built-in electric component as an input/output terminal is electrically connected to a conductive circuit on a front surface through the conductive circuit of a transition layer and the interlayer resin insulation layers via the via-hole.

FIGS. 7(a) to 7(f) are schematic views showing a conventional method of producing a substrate with a built-in electric component. In the conventional method, first, as shown in FIG. 7(a), a GND layer 102 on a first core substrate 101 such as a core substrate with copper clad laminates on both sides thereof is patterned. In the next step, as shown in FIG. 7(b), an electric component 103 having an external electrode and a chip component (discrete receptor component) 104 are soldered and mounted at component mounting positions on the GND layer (power source layer) 102 with a re-flow method and the like. Also, an under-fill 105 is disposed at the external electrode of the electric component 103.

In the next step, as shown in FIG. 7(c), an insulation material 106 such as a prepreg is bored to form component retaining portions 107 and 108. The first core substrate 101 is laminated with the insulation material 106, so that the electric component 103 and the chip component 104 are accommodated in the component retaining portions 107 and 108, respectively. A GND layer (power source layer) 109 on a second core substrate 110 is patterned, and the second core substrate 110 is laminated on the first core substrate 101 with the insulation material 106 in between. Then, as shown in FIG. 7(d), the second core substrate 110 and the first core substrate 101 laminated thereon with the insulation material 106 in between are integrally compressed.

In the next step, as shown in FIG. 7(e), holes are formed with drilling or laser, and the holes are plated to form vias 113 and 114. Accordingly, the GND layer 102 of the first core substrate 101 can be electrically connected to a signal layer 111. Further, the signal layer 111, the GND layer 102, the GND layer 113, and a signal layer 109 of the first core substrate 101 and the second core substrate 110 can be electrically connected. Lastly, as shown in FIG. 7(f), the signal layers 111 and 112 on both sides are patterned to form signal layer patterns with an etching method and the like.
Patent Reference 1: Japanese Patent Publication No. 2006-49762
Patent Reference 2: Japanese Patent Publication No. 2002-9448

In the substrate with the built-in electric component produced with the conventional method as well as a conventional four-layer print circuit board, it is difficult to transmit a signal with good quality to the signal layer opposite to the power source layer due to noises associated with a voltage variance caused by a high speed signal. In particular, it is difficult to dispose a desirable transmission path in the substrate in which a transmission loss has a significant influence.

As described above, a dimension and a weight of a mobile device have been reduced recently, and it has become necessary to make a thickness of a substrate less than 600 μm. However, it is difficult to meet such a requirement with a conventional electric component.

In view of the problems described above, an object of the present invention is to provide an electric component to solve the problems.

Further objects and advantages of the invention will be apparent from the following description of the invention.

### SUMMARY OF THE INVENTION

In order to attain the objects described above, according one aspect of to the present invention, an electric component includes a substrate having a first surface and a second surface opposite to the first surface; a first conductive layer formed on the first surface; a second conductive layer formed on the second surface; an electrode formed on the first conductive layer; a resin portion formed on the first conductive layer such that a part of the electrode is exposed; and an external terminal formed on the first surface and electrically connected to the part of the electrode.

According to another aspect of the present invention, a substrate with a built-in electric component includes a first substrate having a first surface and a second surface opposite to the first surface. The first substrate has a first power source layer formed on the first surface and a first signal layer formed on the second surface. The substrate with the built-in electric component further includes an electric component mounted on the first power source layer. The substrate with the built-in electric component further includes a second substrate having a third surface and a fourth surface opposite to the third surface. The second substrate has a second power source layer formed on the third surface and a second signal layer formed on the fourth surface. The power source layer has a removed portion facing a conductive layer of the electric component. The substrate with the built-in electric component further includes an insulation layer laminated between the first substrate and the second substrate and having a component retaining portion for accommodating the electric component; and a via for electrically connecting the first signal layer and the second signal layer to form a micro-strip line.

In the electric component of the present invention, it is possible to use the conductive layers on the first and second surfaces as a power source layer. Accordingly, it is possible to obtain a thin structure with the power source. The electric component is applicable to a substrate with a built-in electric component having a total thickness of about 600 μm.

In the substrate with the built-in electric component of the present invention, the power source layer has the removed portion facing the conductive layer of the electric component on the first power source layer to form the micro-strip line, so that the conductive layer can be used as the power source layer. Accordingly, it is possible to prevent the second signal layer on the second substrate from being influenced by noises associated with a voltage variance in the power source layer. As a result, it is possible to obtain good signal quality in the signal layer.

### BRIEF DESCRIPTION OF THE DRAWINGS

FIGS. 1(a) to 1(g) are schematic views showing a method of producing an electric component according to a first embodiment of the present invention;

FIGS. 2(a) to 2(h) are schematic views showing a method of producing an electric component according to a second embodiment of the present invention;

FIGS. 3(a) to 3(d) are schematic views showing a method of producing a substrate with a built-in electric component according to a third embodiment of the present invention;

FIG. 4 is a schematic plan view showing the substrate with the built-in electric component according to the third embodiment of the present invention;

FIGS. 5(a) to 5(d) are schematic views showing a method of producing a substrate with a built-in electric component according to a fourth embodiment of the present invention;

FIG. 6 is a schematic plan view showing the substrate with the built-in electric component according to the fourth embodiment of the present invention; and

FIGS. 7(a) to 7(f) are schematic views showing a conventional method of producing a substrate with a built-in electric component.

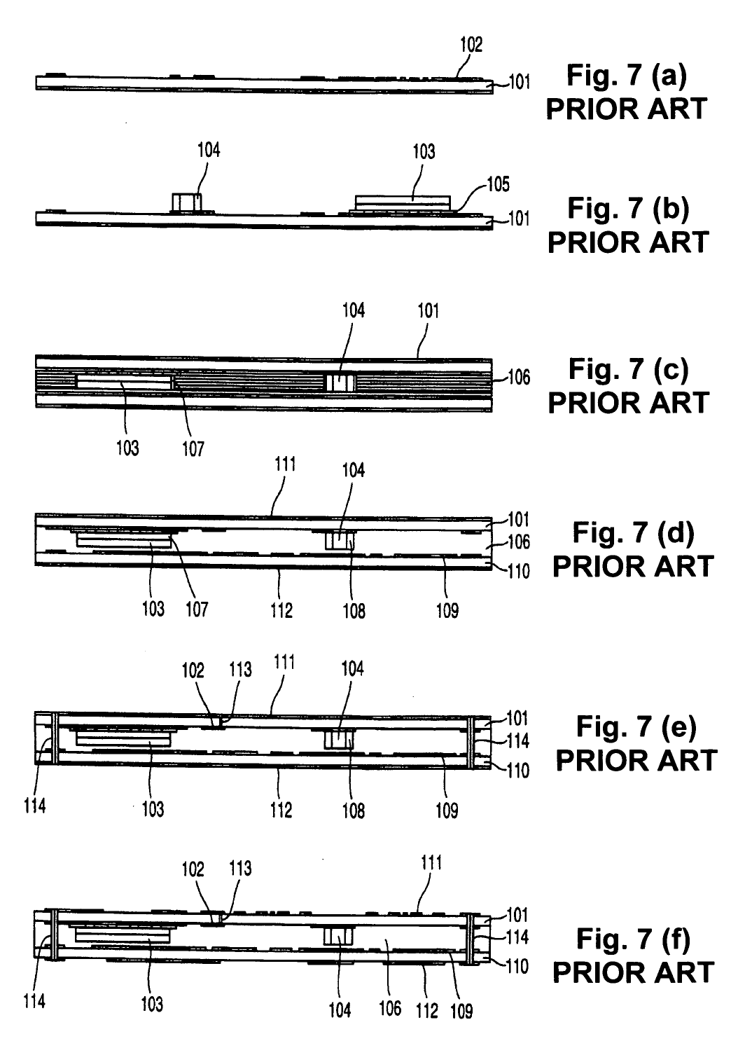

### DETAILED DESCRIPTION OF PREFERRED EMBODIMENTS

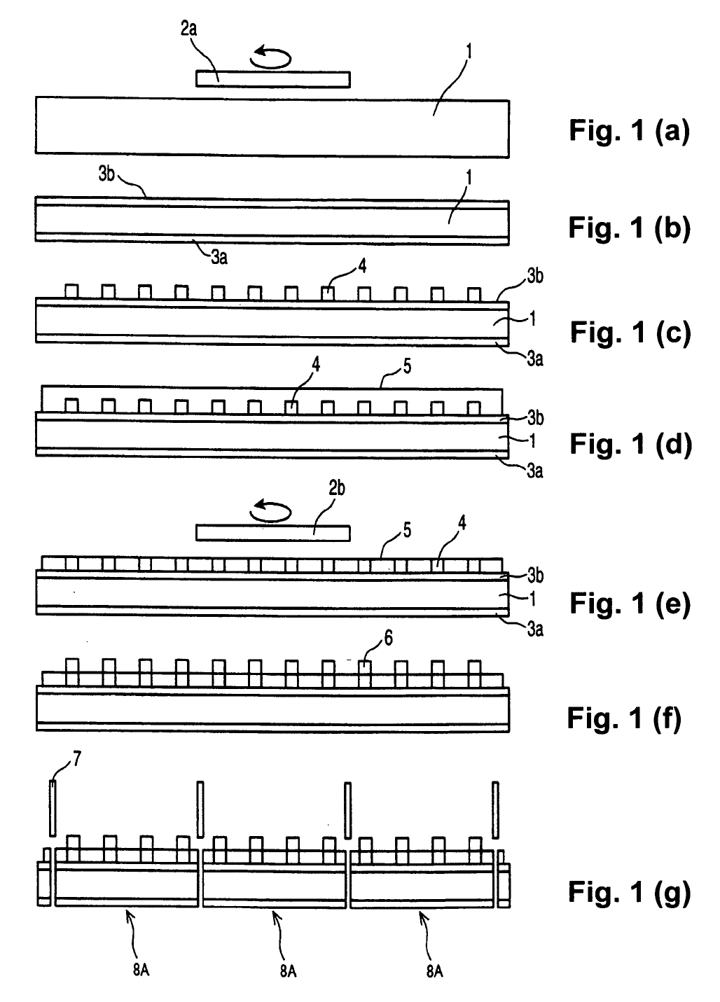

Hereunder, embodiments of the present invention will be explained with reference to the accompanying drawings. FIGS. 1(a) to 1(g) are schematic views showing a method of producing an electric component according to a first embodiment of the present invention. The electric component may include an electric component (W-CSP) having a conductive layer.

First, as shown in FIG. 1(a), a wafer (substrate) 1 is prepared, and both surfaces of the wafer 1 are ground with a fine grinding stone 2a, thereby obtaining a desirable thickness. In the next step, conductive shield layers are formed on the both surfaces of the wafer 1 with sputtering or an electrolytic plating method. Then, as shown in FIG. 1(b), conductive layers 3a and 3b are formed on the both surfaces of the wafer 1 with an electrolytic plating method.

In the next step, as shown in FIG. 1(c), a required number of column electrodes 4 having a column shape are formed on the conductive layer 3b with photolithography or an electrolytic plating method.

In the next step, as shown in FIG. 1(d), the conductive layer 3b and the column electrodes 4 are covered with a sealing resin 5 with a molding method and the like. Then, as shown in FIG. 1(e), the sealing resin 5 is ground with a grinding stone 2b having particles coarser than those of the grinding stone 2a, so that end surfaces of the column electrodes 4 are exposed.

In the next step, as shown in FIG. 1(f), external terminals 6 are formed on the exposed end surfaces of the column electrodes 4 using a metal mask and the like with a screen printing method and the like. At last, as shown in FIG. 1(g), each chip is cut out individually using a dicing blade 7 with a dicing method and the like to obtain an electric component 8A having the conductive layers 3a and 3b.

The electric component 8A having the conductive layers 3a and 3b may be installed in, for example, a four-layer print circuit board. In this case, the external terminals 6 of the electric component 8A are electrically connected to a conductive layer of the four-layer print circuit board, so that the conductive layer 3a can be used as a GND layer (power source layer).

As explained above, in the first embodiment of the present invention, it is possible to accurately adjust a thickness of the wafer through grinding. Further, it is possible to use the conductive layer opposite to the external terminals as the power source layer. Accordingly, it is possible to reduce a thickness of the electric component having the power source layer, and make the electric component applicable to a substrate with a built-in electric component having a total thickness of about 600 μm.

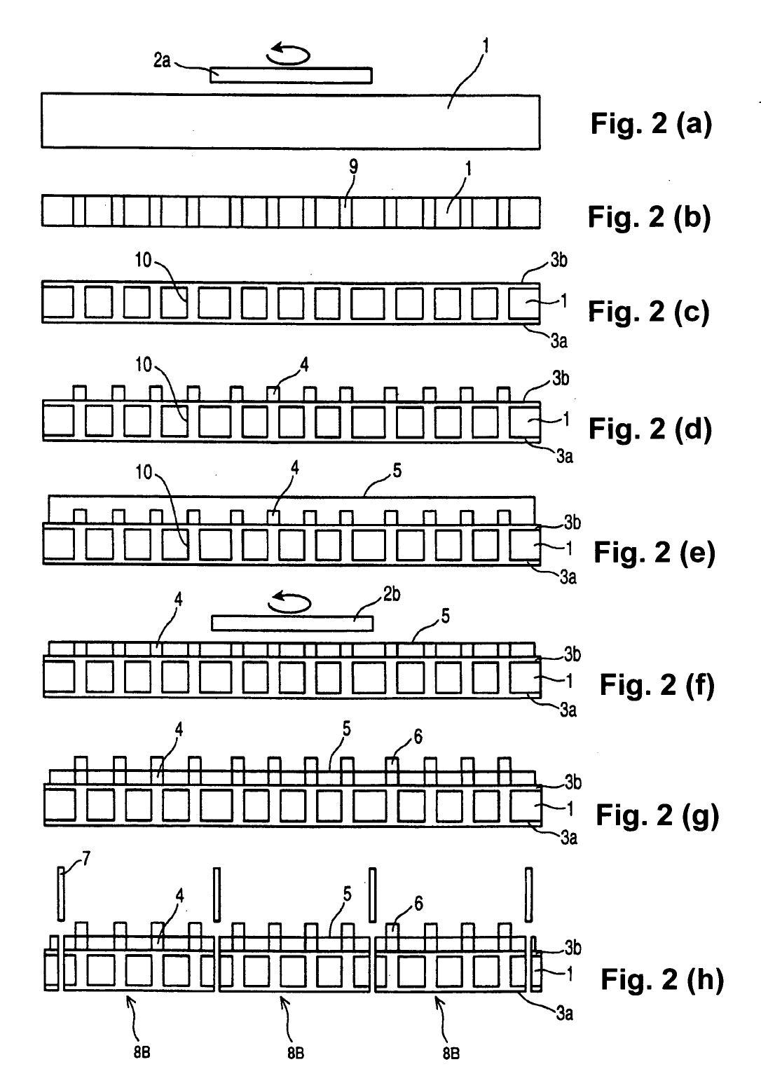

FIGS. 2(a) to 2(h) are schematic views showing a method of producing an electric component to be built-in a substrate according to a second embodiment of the present invention. More specifically, the schematic views show a method of producing an electric component (W-CSP) having a conductive layer and a through via.

First, as shown in FIG. 2(a), the wafer 1 is prepared, and both surfaces of the wafer 1 are ground with a fine grinding stone 2a, thereby obtaining a desirable thickness. In the next step, as shown in FIG. 2(b), a required number of through holes 9 are formed in the wafer 1 with a reactive ion etching method and the like. Then, conductive seed layers are formed on the both surfaces of the wafer 1 and each of the through holes 9 with sputtering or a non-electrolytic plating method. In the next step, as shown in FIG. 2(c), the conductive layers 3a and 3b are formed on the both surfaces of the wafer 1 with an electrolytic plating method, and each of the through holes 9 is plated with an electrolytic plating method to form through vias 10.

In the next step, as shown in FIG. 2(d), a required number of the column electrodes 4 are formed on the conductive layer 3b with photolithography or an electrolytic plating method. In the next step, as shown in FIG. 2(e), the conductive layer 3b and the column electrodes 4 are covered with the sealing resin 5 with a molding method and the like. Then, as shown in FIG. 2(f), the sealing resin 5 is ground with the grinding stone 2b having particles coarser than those of the grinding stone 2a, so that the end surfaces of the column electrodes 4 are exposed.

In the next step, as shown in FIG. 2(g), the external terminals 6 are formed on the exposed end surfaces of the column electrodes 4 using a metal mask and the like with a screen printing method and the like. At last, as shown in FIG. 2(h), each chip is cut out individually using a dicing blade 7 with a dicing method and the like to obtain an electric component 8B having the conductive layers 3a and 3b.

The electric component 8B having the conductive layers 3a and 3b and the through vias 10 may be installed in, for example, a four-layer print circuit board. In this case, the external terminals 6 of the electric component 8A are electrically connected to a conductive layer of the four-layer print circuit board, so that the conductive layer 3a can be used as a GND layer (power source layer).

As explained above, in the second embodiment of the present invention, it is possible to accurately adjust a thickness of the wafer through grinding. Further, it is possible to use the conductive layer opposite to the external terminals as the power source layer. Accordingly, it is possible to reduce a thickness of the electric component having the power source layer, and make the electric component applicable to a substrate with a built-in electric component having a total thickness of about 600 μm. Further, it is possible to dispose the external terminals and the conductive layer at the same potential through the through vias.

In the first and second embodiments described above, the electric components 8A and 8B have the conductive layers 3a and 3b. It is noted that the conductive layer 3b is not necessarily provided. When the conductive layer 3b is not provided, the column electrodes 4 are formed directly on the wafer 1, and the external terminals 6 are provided thereon. In this case, the surface of the wafer 1 with the column electrodes 4 formed thereon is not ground, and only the other surface thereof is ground. The conductive layer 3a is formed on the ground surface. In this case, since the other surface is ground, it is still possible to accurately adjust a thickness of the wafer 1.

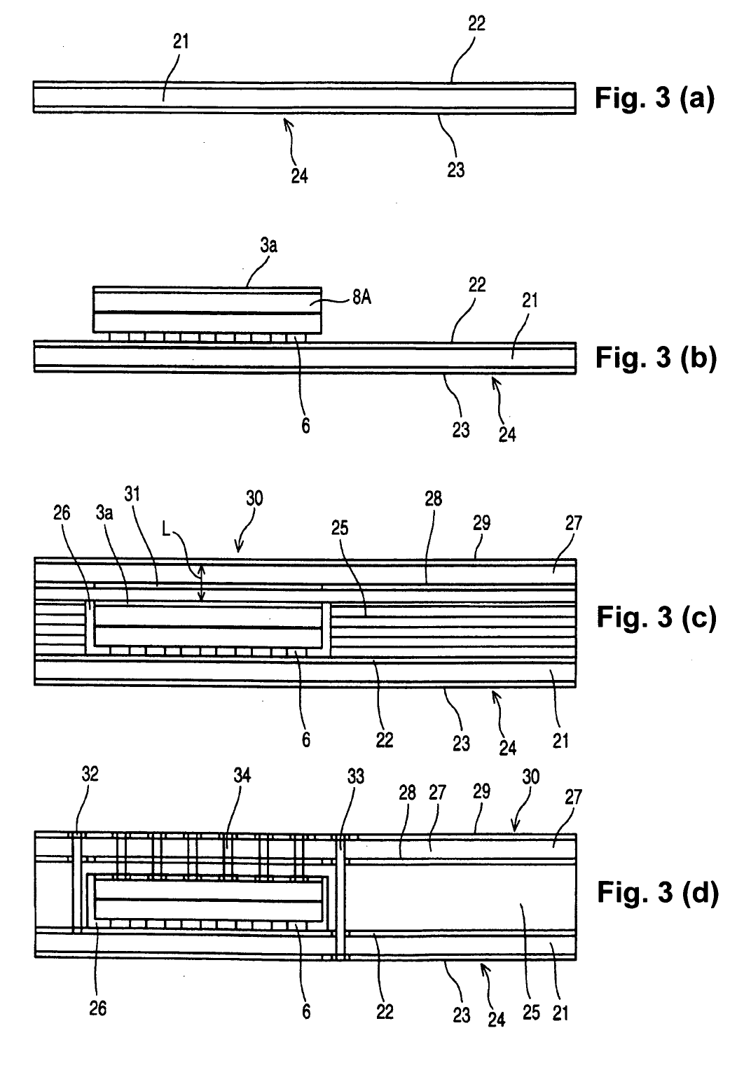

FIGS. 3(a) to 3(d) are schematic views showing a method of producing a substrate with a built-in electric component according to a third embodiment of the present invention.

First, as shown in FIG. 3(a), a first core substrate (both surfaces cupper clad core substrate) 24 is prepared, in which a GND layer (power source layer) 22 and a signal layer 23 are provided on both surfaces of a core 21. Then, the GND layer 22 is patterned with an etching method and the like.

In the next step, as shown in FIG. 3(b), the external terminals 6 of the electric component 8A having the conductive layer 3a or the conductive layers 3a and 3b (produced in the first embodiment) are soldered and mounted at a component mounting position on the GND layer 22 of the first core substrate 24 with a re-flow method and the like.

In the next step, as shown in FIG. 3(c), an insulation material 25 such as a prepreg is counter-bored to form a component retaining portion 26. Similar to the first core substrate 24, a second core substrate 30 is prepared, in which a GND layer (power source layer) 28 and a signal layer 29 are provided on both surfaces of a core 27. A portion of the GND layer 28 of the second core substrate 30 facing the conductive layer 3a of the electric component 8A is removed with etching to form a removed portion 31.

In the next step, the first core substrate 24 is overlapped with the insulation material 25, so that the electric component 8A is accommodated in the component retaining portion 26 of the insulation material 25. Then, the second core substrate 30 is laminated with the first core substrate 24 with the insulation material 25 in between, so that the laminated structure is pressed and integrated.

In the next step, holes are formed at predetermined locations in the first core substrate 24, the insulation material 25, and the second core substrate 30 with a drill and the like, and the holes are plated to form vias 32, 33, and 34 as shown in FIG. 3(d). The via 32 electrically connects the GND layer 24 of the first core substrate 24 to the signal layer 29 of the second core substrate 30. The via 33 electrically connects the signal layer 23 of the first core substrate 24 to the signal layer 29 of the second core substrate 30. The vias 34 electrically connect the signal layer 29 of the second core substrate 30 to the conductive layer 3a of the electric component 8A.

With the configuration described above, it is possible to arrange the conductive layer 3a of the second core substrate 30 at a potential same as that of the external terminals 6. In the last step, the signal layers 23 and 29 are patterned simultaneously with an etching method and the like to form signal patterns, thereby completing the substrate with the built-in electric component.

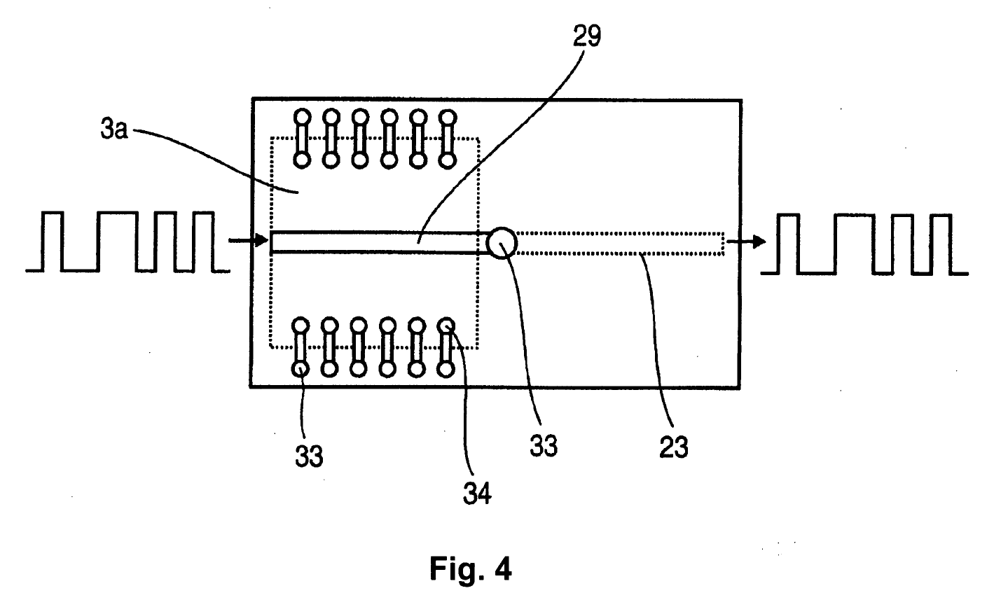

FIG. 4 is a schematic plan view showing the substrate with the built-in electrical component thus produced. With the micro-strip line formed of the signal layer 29 of the second core substrate 30 and the conductive layer 3a of the electric component 8A, a high-speed signal input to an input port is transmitted to the signal layer 29 of the second core substrate 30, and is transmitted to the signal layer 23 of the first core substrate 24 through the via 33, thereby being output. At this time, as shown in FIG. 4, the signal at the output side has a waveform same as that of the signal at the input side.

As described above, in the third embodiment, the electric component produced in the first embodiment is built in the substrate. A portion of the power source layer of the second core substrate facing the conductive layer of the electric component is removed with the etching, so that the micro-strip line is formed, in which the conductive layer of the electric component is used as the power source layer.

In a conventional structure, a signal layer facing a power source layer is easily coupled with a noise due to a voltage variance in the power source layer. In the embodiment of the present invention, on the other hand, the signal layer of the second core substrate is not easily coupled with a noise due to a voltage variance of the power source layer facing the signal layer. Accordingly, it is possible to obtain a signal with good quality and form a high-speed signal line.

Further, similar to the first embodiment, in the electric component built in the substrate, it is possible to accurately adjust a thickness of the wafer through grinding the wafer. Accordingly, it is possible to adjust a distance L shown in FIG. 3(c) between the signal layer of the second core substrate and the conductive layer of the electric component, thereby obtaining desirable characteristic impedance.

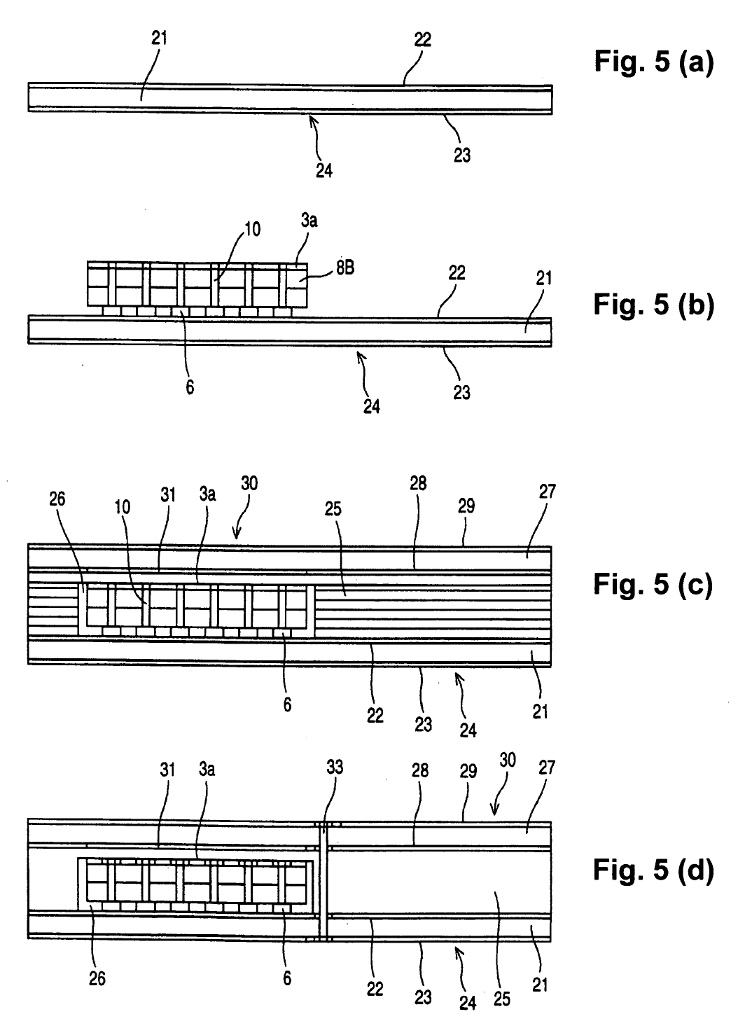

FIGS. 5(a) to 5(d) are schematic views showing a method of producing a substrate with a built-in electric component according to a fourth embodiment of the present invention

First, as shown in FIG. 5(a), the first core substrate (both surfaces cupper clad core substrate) 24 is prepared, in which the GND layer (power source layer) 22 and the signal layer 23 are provided on both surfaces of the core 21. Then, the GND layer 22 is patterned with an etching method and the like.

In the next step, as shown in FIG. 5(b), the external terminals 6 of the electric component 8B having the conductive layer 3a (or the conductive layers 3a and 3b) and the through vias 10 (produced in the second embodiment) are soldered and mounted at a component mounting position on the GND layer 22 of the first core substrate 24 with a re-flow method and the like.

In the next step, as shown in FIG. 5(c), the insulation material 25 is counter-bored to form the component retaining portion 26. A portion of the GND layer 28 of the second core substrate 30 facing the conductive layer 3a of the electric component 8B is removed with etching to form the removed portion 31.

In the next step, the first core substrate 24 is overlapped with the insulation material 25, so that the electric component 8B is accommodated in the component retaining portion 26 of the insulation material 25. Then, the second core substrate 30 is laminated with the first core substrate 24 with the insulation material 25 in between, so that the laminated structure is pressed and integrated.

In the next step, a hole is formed at a predetermined location in the first core substrate 24, the insulation material 25, and the second core substrate 30 with a drill and the like, and the hole is plated to form the via 33 as shown in FIG. 5(d). The via 33 electrically connects the signal layer 23 of the first core substrate 24 to the signal layer 29 of the second core substrate 30.

In the last step, the signal layers 23 and 29 are patterned simultaneously with an etching method and the like to form the signal patterns, thereby completing the substrate with the built-in electric component.

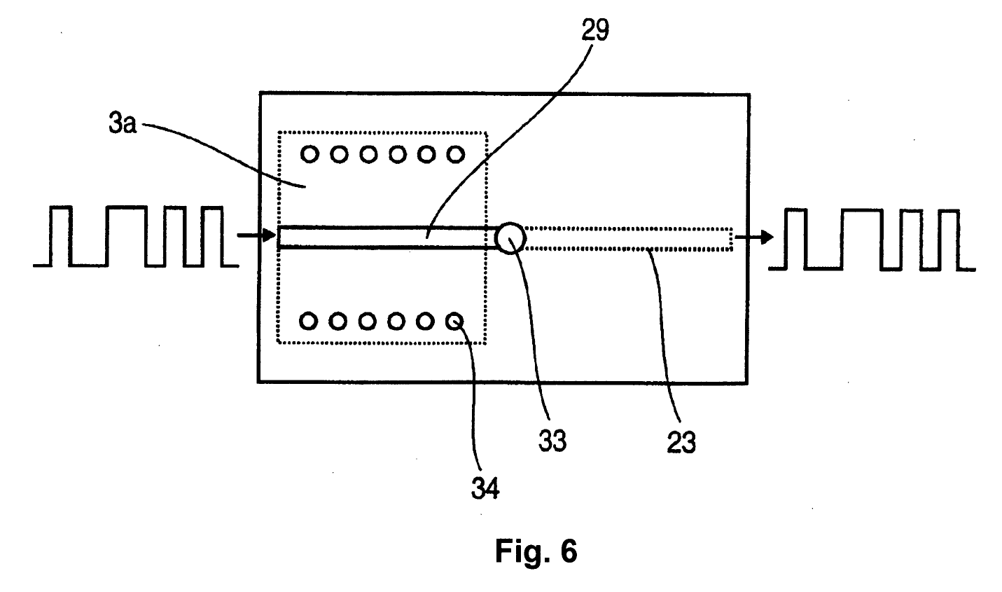

FIG. 6 is a schematic plan view showing the substrate with the built-in electrical component thus produced. Similar to the third embodiment, with the micro-strip line formed of the signal layer 29 of the second core substrate 30 and the conductive layer 3a of the electric component 8B, a high-speed signal input to an input port is transmitted to the signal layer 29 of the second core substrate 30, and is transmitted to the signal layer 23 of the first core substrate 24 through the via 33, thereby being output. At this time, as shown in FIG. 6, the signal at the output side has a waveform same as that of the signal at the input side.

As described above, in the fourth embodiment, the electric component produced in the second embodiment is built in the substrate. A portion of the power source layer of the second core substrate facing the conductive layer of the electric component is removed through the etching, so that the micro-strip line is formed, in which the conductive layer of the electric component is used as the power source layer.

In a conventional structure, a signal layer facing a power source layer is easily coupled with a noise due to a voltage variance in the power source layer. In the fourth embodiment of the present invention, on the other hand, the signal layer of the second core substrate is not easily coupled with a noise due to a voltage variance of the power source layer facing the signal layer. Accordingly, it is possible to obtain a signal with good quality and form a high-speed signal line.

Further, similar to the second embodiment, in the electric component built in the substrate, it is possible to accurately adjust a thickness of the wafer through grinding the wafer. Accordingly, similar to the third embodiment, it is possible to adjust a distance between the signal layer of the second core substrate and the conductive layer of the electric component, thereby obtaining desirable characteristic impedance.

In the third and fourth embodiments, the explanation is limited to the signal transmittance portion of the module. In an actual module, electric components such as an LSI having a driver-receiver function, a discrete semiconductor, an LCR, and a crystal oscillator are mounted on a front layer and an inner layer thereof. The present invention is applicable to any types of modules having a built-in electric component. The substrate of the electric component may include a semiconductor or an insulation material.

The disclosure of Japanese Patent Application No. 2006-130693, filed on May 9, 2006, is incorporated in the application.

While the invention has been explained with reference to the specific embodiments of the invention, the explanation is illustrative and the invention is limited only by the appended claims.

What is claimed is:

1. An electric component comprising:
a substrate having a first surface and a second surface opposite to the first surface;
a first conductive layer formed on the first surface;
a second conductive layer formed on the second surface;
an electrode formed on the first conductive layer;
a resin portion formed on the first conductive layer such that a part of the electrode is exposed; and
an external terminal formed on the first surface and electrically connected to the part of the electrode.

2. The electric component according to claim 1, further comprising a through via penetrating through the substrate for electrically connecting the first conductive layer and the second conductive layer.

3. A method of producing an electric component, comprising the steps of:
preparing a substrate having a first surface and a second surface opposite to the first surface;
forming a first conductive layer on the first surface;
forming a second conductive layer on the second surface;
forming an electrode on the first conductive layer;
forming a resin portion on the first conductive layer such that a part of the electrode is exposed; and
forming an external terminal on the first surface to be electrically connected to the part of the electrode.

4. The method of producing an electric component according to claim 3, further comprising the step of forming a through via penetrating through the substrate for electrically connecting the first conductive layer and the second conductive layer.

5. A substrate with a built-in electric component comprising:
a first substrate having a first surface and a second surface opposite to the first surface, said first substrate including a first power source layer formed on the first surface and a first signal layer formed on the second surface;
an electric component mounted on the first power source layer and having a first conductive layer;
a second substrate having a third surface and a fourth surface opposite to the third surface, said second substrate including a second power source layer formed on the third surface and a second signal layer formed on the fourth surface, said second power source layer including a removed portion facing the first conductive layer of the electric component;
an insulation layer laminated between the first substrate and the second substrate and having a component retaining portion for accommodating the electric component; and
a via for electrically connecting the first signal layer and the second signal layer to form a micro-strip line.

6. The substrate with the built-in electric component according to claim 5, wherein said electric component includes:
a third substrate having a fifth surface and a sixth surface opposite to the fifth surface;
the first conductive layer formed on the fifth surface;
a second conductive layer formed on the sixth surface;
an electrode formed on the second conductive layer;
a resin portion formed on the second conductive layer such that a part of the electrode is exposed; and
an external terminal formed on the sixth surface and electrically connected to the part of the electrode.

7. A method of producing a substrate with a built-in electric component, comprising the steps of:
preparing a first substrate having a first surface and a second surface opposite to the first surface;
forming a first power source layer on the first surface;
forming a first signal layer on the second surface;
mounting an electric component on the first power source layer, said electric component having a first conductive layer;
forming a component retaining portion in an insulation layer for accommodating the electric component;
preparing a second substrate having a third surface and a fourth surface opposite to the third surface;
forming a second power source layer on the third surface;
forming a second signal layer on the fourth surface;
removing a part of the second power source layer facing the first conductive layer of the electric component to form a removed portion;
laminating the insulation layer between the first substrate and the second substrate; and
forming a via for electrically connecting the first signal layer and the second signal layer to form a micro-strip line.

8. The method of producing a substrate with a built-in electric component according to claim 7, wherein said electric component includes:
a third substrate having a fifth surface and a sixth surface opposite to the fifth surface;
the first conductive layer formed on the fifth surface;
a second conductive layer formed on the fifth surface;
an electrode formed on the second conductive layer;
a resin portion formed on the second conductive layer such that a part of the electrode is exposed; and
an external terminal formed on the sixth surface and electrically connected to the part of the electrode.

9. The method of producing a substrate with a built-in electric component according to claim 8, wherein said electric component further includes a through via penetrating through the third substrate for electrically connecting the first conductive layer and the second conductive layer.
